(19) United States
(12) Patent Application Publication
(10) Pub. No.: US 2009/0215254 A1
(43) Pub. Date: Aug. 27, 2009

(54) Design support system,computer readable medium, semiconductor device designing method and semiconductor device manufacturing method

(75) Inventor: Hirokazu Aizawa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/379,169

(22) Filed: Feb. 13, 2009

(30) Foreign Application Priority Data
Feb. 22, 2008 (JP) 42223/2008

(51) Int. Cl. H01L 21/02; G06F 17/50

(52) U.S. Cl. 438/585; 716/1; 257/E21.002

(57) ABSTRACT

A design support system which supports designing a semiconductor device is provided. The design support system includes a gate film information acquisition section and a maximum allowable antenna ratio setting section. The gate film information acquisition section acquires information on the thickness of the gate insulating film of a semiconductor device which has been designed. The gate insulating film thickness refers to a physical film thickness. The maximum allowable antenna ratio setting section sets maximum allowable antenna ratios for a gate electrode according to the film thickness information acquired by the gate film information acquisition section. Hence, a designer designing a semiconductor device can set concrete values when changing maximum allowable antenna ratios according to the thickness of the gate insulating film.

### BACKGROUND OF THE INVENTION

1. Field of the Invention

The present invention relates to a design support system, a computer readable medium, semiconductor device designing method and semiconductor device manufacturing method.

2. Description of Related Art

A semiconductor device like a transistor having a gate insulating film and a gate electrode includes contact plugs, upper layer wirings, and via-holes which are connected to the gate electrode. In the process of manufacturing such a semiconductor device, electric charges are accumulated in contact plugs, upper layer wirings, and via-holes connected to a gate electrode, possibly causing the electric charges to be discharged to the semiconductor substrate and, as a result, the gate insulating film to deteriorate.

To prevent such problems, in designing a semiconductor device, maximum allowable antenna ratios are set. An antenna ratio is calculated by dividing the area of a gate electrode and via-holes and upper layer wirings which are connected to the gate electrode (hereinafter referred to as an “antenna electrode”) by the gate area. When designing wirings and via-holes of a semiconductor device, the designer makes sure that their antenna ratios do not exceed the maximum allowable values set for them. When the maximum allowable antenna ratios are excessively low, flexibility in wiring designing is reduced.

In the technique disclosed in JP-A-2004-152929, antenna criteria applied to MOS transistors which are among the MOS transistors of different gate insulating film thicknesses included in a semiconductor device and whose gate insulating film thicknesses do not exceed a predetermined film thickness are made less strict than those applied to other MOS transistors which are also included in the same semiconductor device and whose gate insulating film thicknesses exceed the predetermined film thickness. To be concrete, it is stated in JP-A-2004-152929 that the antenna criteria applied to MOS transistors whose gate insulating films are thinner than 2.6 nm, i.e. a threshold film thickness below which charge tunneling does not occur, are made less strict than those applied to MOS transistors having thicker gate insulating films. It is also stated that applying less strict design criteria to MOS transistors having thin gate insulating films increases flexibility in designing and manufacturing semiconductor devices.

The present inventor has recognized as follows. According to the above existing technique, it is not clear how the maximum allowable antenna ratios that are made different according to the film thickness of the gate insulating film are determined.

### SUMMARY

The present invention provides a design support system which includes: a gate film information acquisition section which acquires a film thickness of a gate insulating film; and a maximum allowable antenna ratio setting section which sets a maximum allowable antenna ratio for a gate electrode positioned on the gate insulating film and which makes the maximum allowable antenna ratio different according to the film thickness read by the gate film information acquisition section.

The present invention also provides a computer readable medium storing a program executed in a computer. The program comprises: acquiring a film thickness of a gate insulating film; and setting a maximum allowable antenna ratio for a gate electrode positioned on the gate insulating film and varying the maximum allowable antenna ratio according to the film thickness read by the first function of the gate insulating film.

The present invention also provides a method of designing a semiconductor. The method includes generating design data on wiring to be connected to a gate electrode; having a computer set a maximum allowable antenna ratio for the gate electrode; having the computer calculate an antenna ratio of the gate electrode using the design data; and having the computer determine whether the calculated antenna ratio is either equal to or smaller than the maximum allowable antenna ratio and output a result of determination. In the step of setting the maximum allowable antenna ratio, the computer varies the maximum allowable antenna ratio according to the film thickness of a gate insulating film under the gate electrode.

The present invention also provides a method of manufacturing a semiconductor device. The method includes designing, by the above design method, a semiconductor device including a gate insulating film, a gate electrode, and an upper layer wiring; and manufacturing the semiconductor device according to a design which is designed in the step of designing.

According to the present invention, when changing a maximum allowable antenna ratio for a semiconductor device based on the thickness of the gate insulating film, the designer designing the semiconductor device can specify a concrete value.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram of the functional configuration of a design support system according to a first embodiment of the present invention;

FIG. 2 is a plan view of a designed semiconductor device;

FIG. 3 is a sectional view taken along line A-A′ of FIG. 2;

FIG. 4 shows a table listing part of design data stored in a design data base;

FIG. 5 shows an example data composition in a maximum allowable antenna ratio table;

FIG. 6 is a graph showing relationship between wiring antenna ratio and gate insulating film thickness (gate film thickness);

FIG. 7 is a graph showing relationship between wiring antenna ratio and gate insulating film thickness (gate film thickness);

FIG. 8 is a graph representing a first example function held in a maximum allowable antenna ratio function holding section;

FIG. 9 is a graph representing a second example function held in the maximum allowable antenna ratio function holding section;

FIG. 10 is a graph representing a third example function held in the maximum allowable antenna ratio function holding section;

FIG. 11 is a flowchart for explaining a method of designing a semiconductor device using the design support system;

FIG. 12 is a flowchart showing first example details of a maximum allowable antenna ratio setting process (S120) shown in FIG. 11;

FIG. 13 is a flowchart showing second example details of the maximum allowable antenna ratio setting process (S120) shown in FIG. 11;

FIG. 14 is a block diagram of the configuration of a design support system according to a second embodiment of the invention;

FIG. 15 is a flowchart for explaining a first example process for setting maximum allowable antenna ratios using the design support system shown in FIG. 14;

FIG. 16 is a flowchart for explaining a second example process for setting maximum allowable antenna ratios using the design support system shown in FIG. 14; and

FIG. 17 is a flowchart for explaining operation of a design support system according to a third embodiment of the invention.

### DETAILED DESCRIPTION OF THE PREFERRED EMBODIMENTS

Preferred embodiments of the present invention will be described below with reference to drawings. In the attached drawings, like elements and like processing steps are assigned like reference numerals and like step numbers, respectively, and their descriptions are omitted where appropriate to avoid duplication.

### First Embodiment

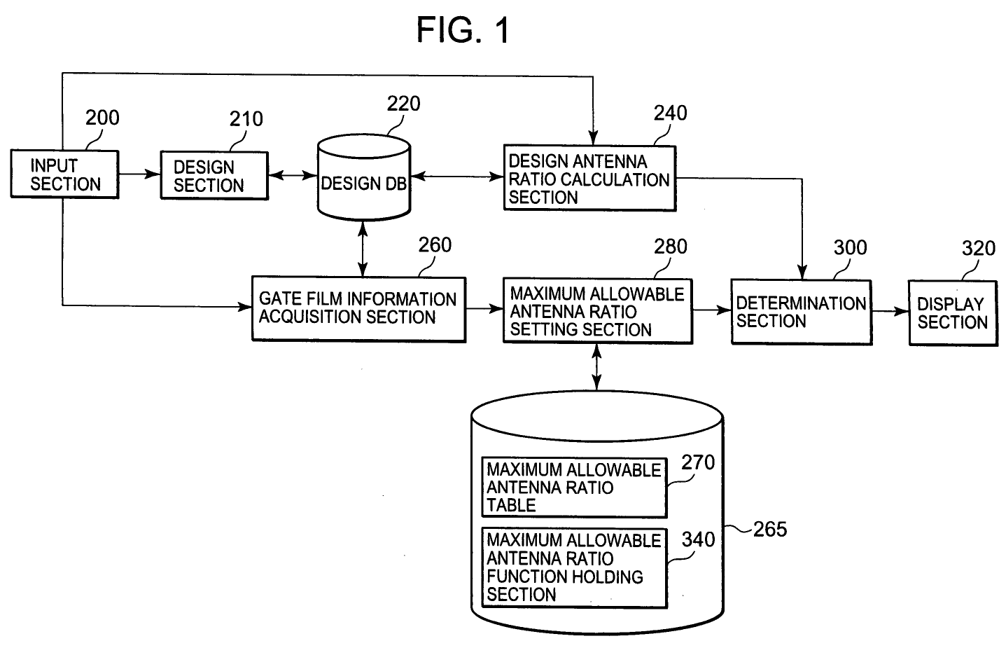

FIG. 1 is a block diagram of the functional configuration of a design support system according to a first embodiment of the present invention. The design support system supports designing a semiconductor device. The design support system includes a gate film information acquisition section 260 and a maximum allowable antenna ratio setting section 280. The gate film information acquisition section 260 acquires information on the thickness of the gate insulating film of a semiconductor device which has been designed. The gate insulating film thickness refers to a physical film thickness. The maximum allowable antenna ratio setting section 280 sets maximum allowable antenna ratios for a gate electrode according to the film thickness information acquired by the gate film information acquisition section 280. Hence, a designer designing a semiconductor device can set concrete values when changing maximum allowable antenna ratios according to the thickness of the gate insulating film. This will be explained in detail in the following.

The design support system shown in FIG. 1 has an input section 200, a design section 210, a design data base (hereinafter referred to as a “design DB”) 220, a design antenna ratio calculation section 240, the gate film information acquisition section 260, a maximum allowable antenna ratio setting information holding section 265, the maximum allowable antenna ratio setting section 280, a determination section 300, and a display section 320.

The input section 200 is for use by a designer in inputting information to the design support system. It is, for example, a keyboard or mouse. The information inputted from the input section 200 includes various kinds of control information for use in the design support system. The design section 210 generates semiconductor device design data using the information inputted from the input section 200. The design DB 220 stores the semiconductor device design data generated by the design section 210. The design antenna ratio calculation section 240 calculates, using the design data stored in the design DB 220, antenna ratios of the designed semiconductor device. The gate film information acquisition section 260 reads, from the design DB 220, the thickness of the gate insulating film used in the designed semiconductor device.

The maximum allowable antenna ratio setting information holding section 265 holds information required to set maximum allowable antenna ratios based on the thickness of the gate insulating film. In the present embodiment, the maximum allowable antenna ratio setting information holding section 265 includes a maximum allowable antenna ratio table 270 and a maximum allowable antenna ratio function holding section 340. The maximum allowable antenna ratio table 270 holds maximum allowable antenna ratios corresponding to different gate insulating film thicknesses. The maximum allowable antenna ratio function holding section 340 holds data representing a function which includes an independent variable representing a gate insulating film thickness and a dependent variable representing a maximum allowable wiring antenna ratio.

The maximum allowable antenna ratio setting section 280 sets maximum allowable antenna ratios using information on the gate insulating film thickness acquired by the gate film information acquisition section 260 and the information held in the maximum allowable antenna ratio setting information holding section 265. The determination section 300 determines whether the antenna ratios calculated by the design antenna ratio calculation section 240 are either equal to or lower than the corresponding maximum allowable antenna ratios set by the maximum allowable antenna ratio setting section 280. The display section 320 is, for example, a display unit which displays the result of determination of the determination section 300. By looking at the display outputted to the display section 320, the designer can know whether the designed semiconductor device meets the corresponding antenna ratio criteria.

The constituent elements of the design support system shown in FIG. 1 can be realized by arbitrarily combining hardware and software including the CPU and memory of a computer, a program loaded in the memory, a storage unit, for example, a hark disk storing the program, and an interface for network connection. As will be understood by those skilled in the art, there are various modified ways of realizing the constituent elements of the design support system and various different devices can be incorporated in the system.

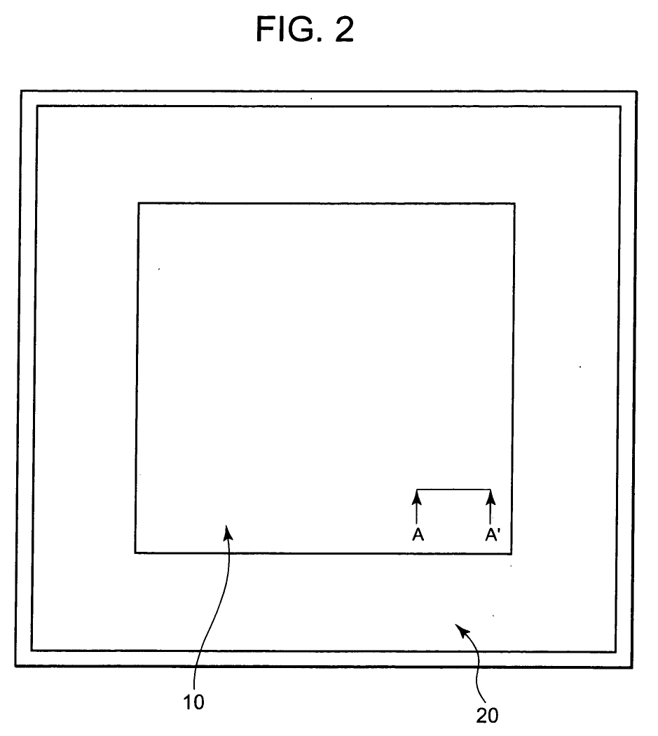

FIG. 2 is a plan view of a designed semiconductor device which includes a central area 10 and a peripheral area 20. A memory circuit and a logic circuit are formed in the central area 10. The memory circuit and logic circuit include a first transistor. An input/output circuit including a second transistor is formed in the peripheral area 20. The gate insulating film of the second transistor is thicker than that of the first transistor. The first transistor formed in the central area 10 and the second transistor formed in the peripheral area 20 are electrically connected via upper layer wirings.

The peripheral area 20 may include a third transistor and a fourth transistor. In such a case, the second to fourth transistors mutually differ in gate insulating film thickness, but their gate insulating film thicknesses are greater than that of the first transistor.

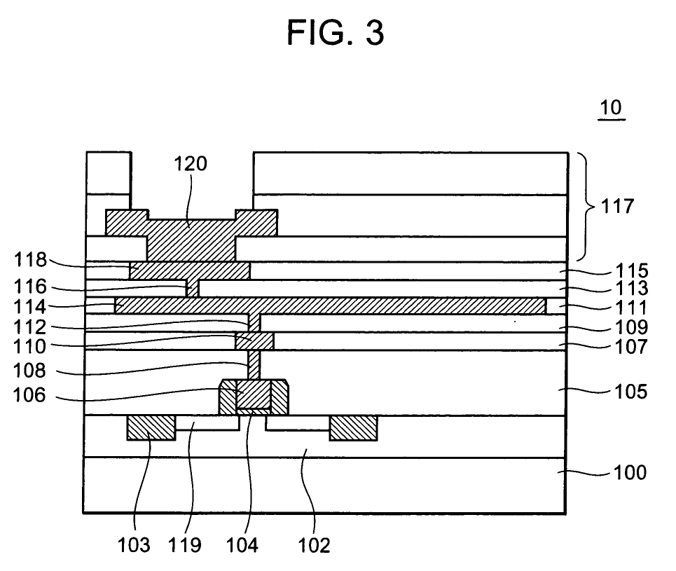

FIG. 3 is a sectional view taken along line A-A′ of FIG. 2. The first transistor is formed in the central area 10. The first transistor has a well 102, a gate insulating film 104, a gate electrode 106, and a diffusion layer 119 which are formed in a semiconductor substrate 100. The first transistor is isolated from other parts by a shallow trench isolation (STI) 103. A first layer wiring 110, a second layer wiring 114, a third layer wiring 118, and a pad 120 are formed over the first transistor. The wiring 110 and a gate electrode 106 are connected via a contact 108. The wirings 110 and 114 are connected via a first via-hole 112. The wirings 114 and 118 are connected via a second via-hole 116. The pad 120 is connected to the wiring 118. The contact 108 is formed in a contact interlayer dielectric film 105. The wiring 110 is formed in a first wiring interlayer dielectric film 107. The first via-hole 112 is formed in a first via-hole interlayer dielectric film 109. The wiring 114 is formed in a second wiring interlayer dielectric film 111. The second via-hole 116 is formed in a second via-hole interlayer dielectric film 113. The wiring 118 is formed in a third wiring interlayer dielectric film 115. A cover film 117 is formed over the third wiring interlayer dielectric film 115. The peripheral area 20 shown in FIG. 2 has a same sectional structure as the structure shown in FIG. 3.

When the semiconductor device shown in FIGS. 2 and 3 is fabricated, the gate electrode 106, contact 108, wirings 110, 114, and 118, via-holes 112 and 116, and pad 120 which collect electric charges make up an antenna electrode. It is necessary to define the ratios of the areas of these elements to the area of the gate insulating film as antenna ratios and set maximum allowable-values for the antenna ratios. In the present embodiment, four kinds of antenna ratios are used. They are a wiring antenna ratio, a via-hole antenna ratio, a contact antenna ratio, and a pad antenna ratio. In the present embodiment: the wiring antenna ratio is calculated by dividing the sum of areas of a gate electrode (in the example shown in FIG. 3, the gate electrode 106) and wirings (in the example shown in FIG. 3, the wirings 110, 114, and 118) by the area of the gate insulating film; the via-hole antenna ratio is calculated by dividing the sum of areas of via-holes (in the example shown in FIG. 3, the via-holes 112 and 116) by the area of the gate insulating film; the contact antenna ratio is calculated by dividing the sum of areas of contacts (in the example shown in FIG. 3, the contact 108) by the area of the gate insulating film; and the pad antenna ratio is calculated by dividing the sum of areas of pads (in the example shown in FIG. 3, the pad 120) by the area of the gate insulating film.

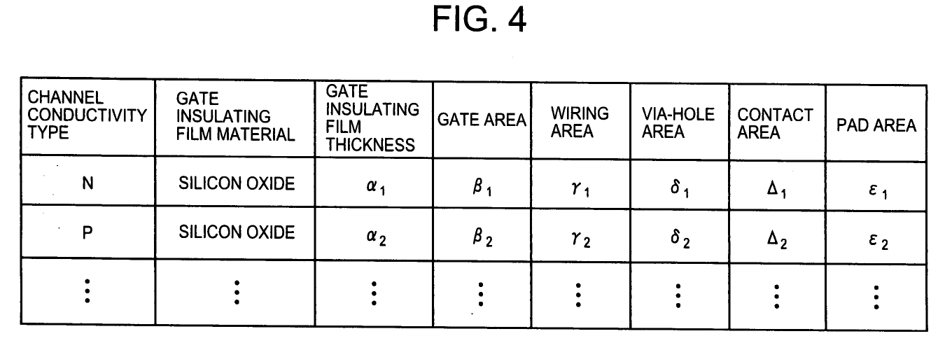

FIG. 4 is a table listing example design data stored in the design DB 220. The design DB 220 stores design data on each transistor included in the semiconductor device. Such design data includes conductivity type information indicating whether the transistor is of an N-channel type or of a P-channel type, information on the gate insulating film such as film material, film thickness, and film area (gate area), and other kinds of information indicating, for example, the sum of areas of the gate electrode and wirings (hereinafter referred to as a “wiring area”), the sum of design areas of via-holes (hereinafter referred to as a “via-hole area”), the sum of design areas of contacts (hereinafter referred to as a “contact area”), and the sum of areas of pads (hereinafter referred to as a “pad area”).

The gate insulating film materials that may be used include silicon oxide and high-dielectric-constant material. High-dielectric-constant material is higher in relative permittivity than silicon oxide. Namely, a high-k film may be used for gate insulation. The high-dielectric-constant material to be used may be one with a relative permittivity of 10 or higher. To be concrete, the high-dielectric-constant material may be a silicate containing at least one out of a group of elements including hafnium (Hf), zirconium (Zr), and lanthanoid element and nitrogen (N).

The information on gate insulating film area may indicate a gate area, or a gate width and a gate length. The information on wiring area and pad area may indicate a wiring area and a pad area; the area of each wiring and the area of each pad; or the width, length, and boundary length of each wiring and the width, length, and boundary length of each pad. The information on via-hole area and contact area may indicate a via-hole area and a contact area; the design area of each via-hole and the design area of each contact hole; or the design length of a side of each via-hole and the design length of a side of each contact.

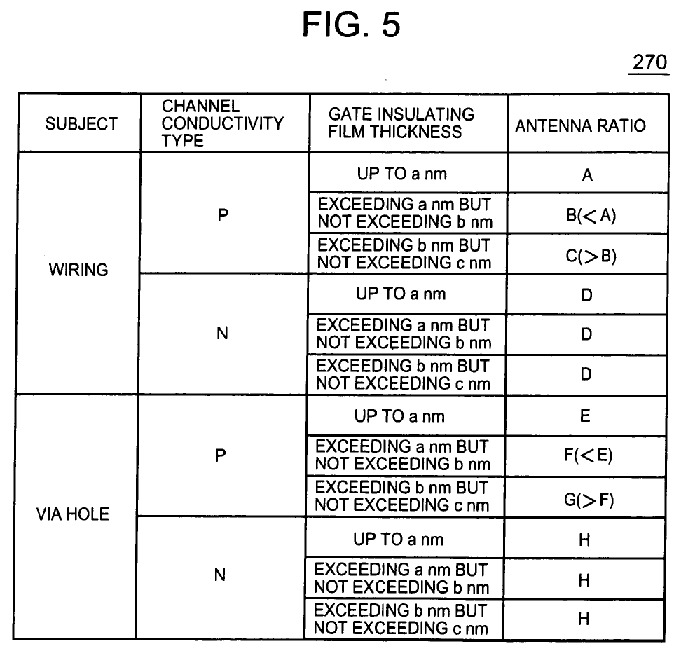

FIG. 5 shows an example data composition in the maximum allowable antenna ratio table 270. The maximum allowable antenna ratio table 270 holds maximum allowable wiring antenna ratios and via-hole antenna ratios by channel conductivity type and gate insulating film thickness range. In the maximum allowable antenna ratio table 270 shown in FIG. 5, the gate insulating film thicknesses are classified into three ranges: a first range of thicknesses exceeding a nm but not exceeding b nm; a second range of thicknesses not exceeding a nm; and a third range of thicknesses exceeding b nm but not exceeding c nm.

For a P-channel transistor, the maximum allowable antenna ratio table 270 holds A, B, and C as the maximum allowable wiring antenna ratios corresponding to gate insulating film thicknesses of the second range, first range, and third range, respectively. In this case, A is higher than B (A>B), and C is higher than B (C>B). A may be equal to C (A=C).

For a P-channel transistor, the maximum allowable antenna ratio table 270 holds E, F, and Gas the maximum allowable via-hole antenna ratios corresponding to gate insulating film thicknesses of the second range, first range, and third range, respectively. In this case, E is higher than F (E>F), G is higher than F (G>F), and C is higher than each of E and G (C>E and C>G). E may be equal to G (E=G).

For an N-channel transistor, the maximum allowable antenna ratio table 270 holds D and H as the maximum allowable wiring antenna ratio and via-hole antenna ratio, respectively, regardless of the gate insulating film thickness range. In this case, D is higher than B (D>B) and H is higher than F (H>F). D may be equal to A or C (D=A or C), or H may be equal to E or G (H=E or G).

As described above, maximum allowable antenna ratios can be less strict for an N-channel transistor than for a P-channel transistor. This is because electric charges accumulated at an antenna electrode are negative. Namely, when a gate electrode is made of polysilicon, the gate electrode and well are of mutually different conductivity types and make up a diode. When, in such a case, the transistor is of an N-channel type, the negative charges at the antenna electrode cause the diode to be subjected to a forward voltage. This makes it easier for the negative charges to be discharged into the well. When the transistor is of a P-channel type, on the other hand, the negative charges at the antenna electrode cause the diode to be subjected to a reverse voltage. This makes it less easy for the negative charges to be discharged into the well.

For an N-channel transistor, the maximum allowable wiring antenna ratios and via-hole antenna ratios corresponding to the gate insulating film thicknesses of the second and third ranges held in the maximum allowable antenna ratio table 270 may be higher than those corresponding to the gate insulating film thicknesses of the first range. Like the wiring antenna ratios and via-hole antenna ratios, contact antenna ratios and pad antenna ratios are also held in the maximum allowable antenna ratio table 270.

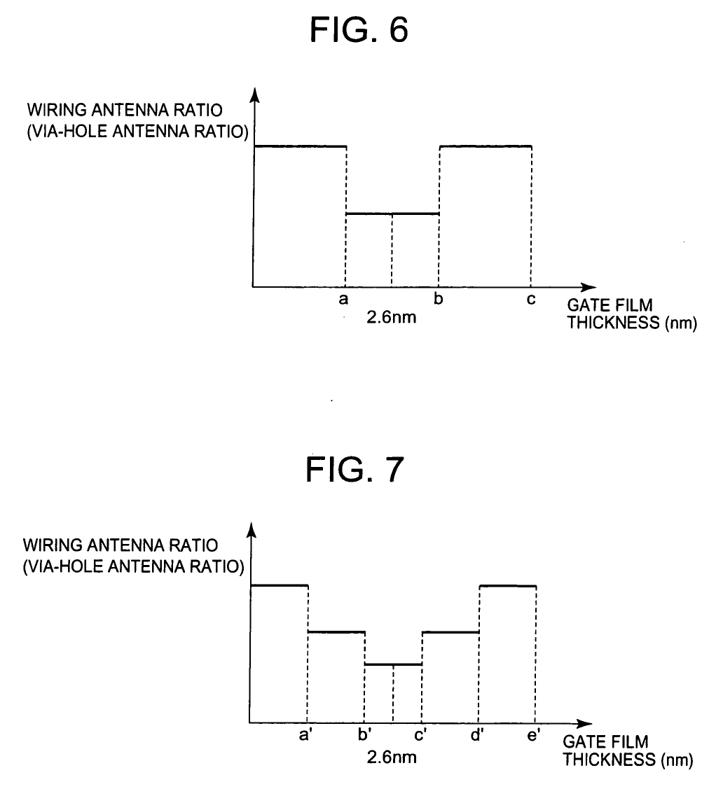

FIG. 6 is a graph showing relationship between the wiring antenna ratio and gate insulating film thickness (gate film thickness) of a P-channel transistor in a case where the data held in the maximum allowable antenna ratio table 270 is composed as shown in FIG. 5. The wiring antenna ratio is lowest when the gate film thickness is in the first range (i.e. when the gate insulating film thickness exceeds a nm without exceeding b nm). When the gate insulating film is formed of silicon oxide, a gate insulating film thickness of 2.6 nm is included in the first range. When a gate insulating film of silicon oxide is 2.6 nm thick, a tunneling current starts being generated. Therefore, the maximum allowable antenna ratio can be made higher when the gate insulating film thickness is smaller than 2.6 nm. As the gate insulating film thickness is increased beyond 2.6 nm, on the other hand, the dielectric strength of the gate insulating film increases, so that the maximum allowable antenna ratio can be made higher.

The relationship between the via-hole antenna ratio, contact antenna ratio, or pad antenna ratio and the gate insulating film thickness is also as shown by FIG. 6.

FIG. 7 is a graph showing relationship between the wiring antenna ratio and gate insulating film thickness (gate film thickness) of a P-channel transistor in a case where the data composition in the maximum allowable antenna ratio table 270 is different from that shown in FIG. 5. In the case shown in FIG. 7, the gate insulating film thickness is divided into five ranges in the maximum allowable antenna ratio table 270. The maximum allowable antenna ratio table 270 holds maximum allowable wiring antenna ratios and via-hole antenna ratios corresponding to the five ranges of gate insulating film thicknesses.

As described above, the gate insulating film thickness may be divided into narrower ranges in the maximum allowable antenna ratio table 270, and the table may hold maximum allowable wiring antenna ratios and via-hole antenna ratios corresponding to such narrower ranges.

The maximum allowable antenna ratio function holding section 340 holds, for each transistor conductivity type, data representing a function which includes an independent variable representing a gate insulating film thickness and a dependent variable representing a maximum allowable wiring antenna ratio and data representing a function which includes an independent variable representing a gate insulating film thickness and a dependent variable representing a maximum allowable via-hole antenna ratio.

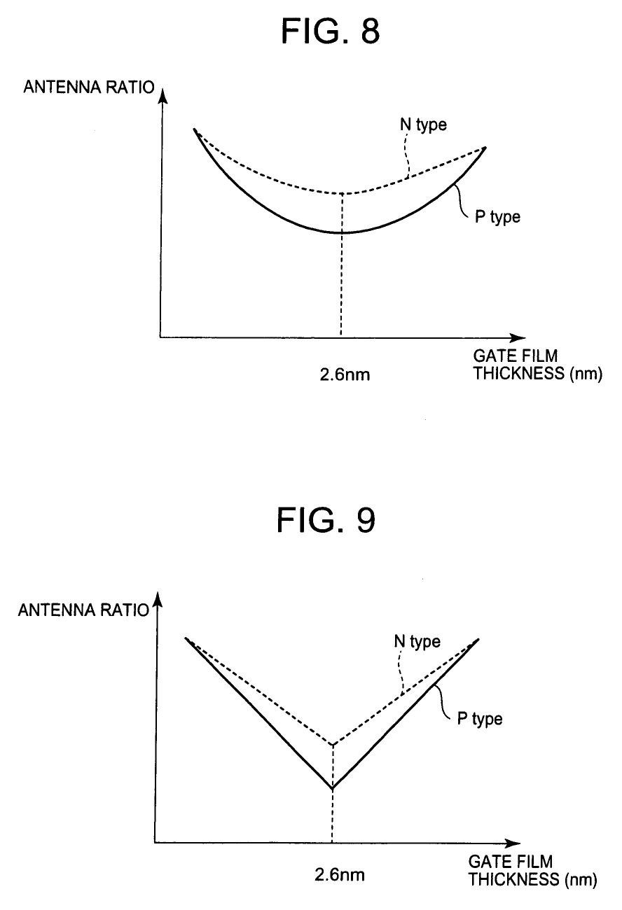

FIG. 8 is a graph representing a first example function represented by data held in the maximum allowable antenna ratio function holding section 340. Each of the curves shown in the graph is approximately U-shaped with an extremal value represented by a bottom portion thereof.

FIG. 9 is a graph representing a second example function represented by data held in the maximum allowable antenna ratio function holding section 340. Each of the curves shown in the graph is approximately V-shaped with an extremal value represented by a bottom portion thereof.

FIG. 10 is a graph representing a third example function represented by data held in the maximum allowable antenna ratio function holding section 340. Each of the curves shown in the graph is approximately U-shaped having a horizontal bottom portion.

The example functions represented in FIGS. 8, 9, and 10 apply to any of the wiring antenna ratios, via-hole antenna ratios, contact antenna ratios, and pad antenna ratios. In whichever case, when a gate insulating film of silicon oxide is used, the maximum allowable antenna ratio is smallest for a gate insulating film thickness of 2.6 nm. This is because, as explained with reference to FIG. 6, when the gate insulating film is 2.6 nm thick, a tunneling current starts being generated.

In any case, the extremal value of the function is smaller for a P-channel transistor than for an N-channel transistor. However, when the gate film thickness is smaller or larger than the extremal value of the corresponding function, the difference between the maximum allowable antenna ratios for a P-channel transistor and an N-channel transistor is smaller. This is because a thinner gate insulating film causes the tunneling current to increase and the electric charges accumulated at the antenna electrode to decrease and also because a thicker gate electrode causes the dielectric strength of the gate electrode to increase.

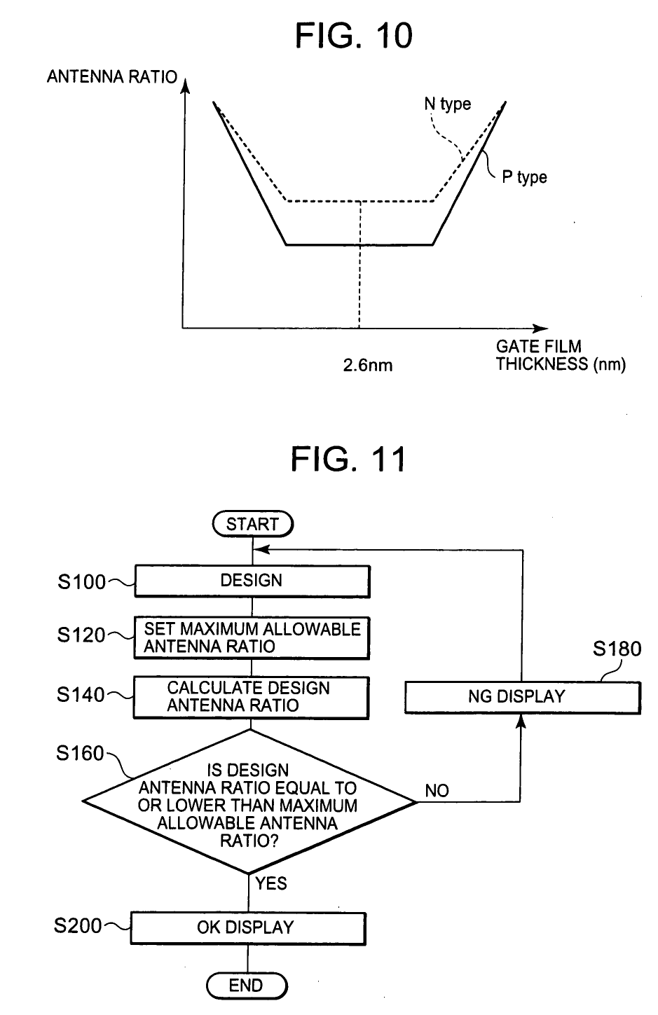

FIG. 11 is a flowchart for explaining a method of designing a semiconductor device using the design support system shown in FIG. 1. First, the designer designs a semiconductor device by inputting required data to the design section 210. What is designed in this step includes wirings, contacts, via-holes, and pads to be connected to each gate electrode. The semiconductor device design data generated in this step is stored in the design DB 220 (S100).

When step S100 is completed, the designer makes the design support system determine whether designed antenna ratios meet predetermined criteria. When a command for checking antenna ratios is inputted to the input section 200, the design support system sets a maximum allowable wiring antenna ratio, a maximum allowable via-hole antenna ratio, a maximum allowable contact antenna ratio, and a maximum allowable pad antenna ratio for each of plural transistors (S120). This process of setting maximum allowable antenna ratios will be described in detail later with reference to a flowchart.

The design antenna ratio calculation section 240 of the design support system reads, from the design DB 200, information on gate insulating film areas, wiring areas, via-hole areas, contact areas, and maximum allowable pad antenna ratios, and calculates, using the information thus read, the wiring antenna ratio, via-hole antenna ratio, contact antenna ratio, and pad antenna ratio for each transistor included in the designed semiconductor device (S140).

The determination section 300 of the design support system determines, for each transistor, whether the wiring antenna ratio, via-hole antenna ratio, contact antenna ratio, and pad antenna ratio calculated in step S140 are either equal to or lower than the corresponding maximum allowable antenna ratio set in step S120 (S160). If any antenna ratio calculated in step S140 for any transistor is found to be higher than the corresponding maximum allowable antenna ratio set in step S120 (S160: NO), the determination section 300 outputs NG information specifying the particular transistor to the display section 320. The display section 320 displays the inputted NG information for recognition by the designer (S180). The designer, after recognizing the NG information, re-designs the semiconductor device (S100).

When no antenna ratio calculated in step S140 is found to be higher than the corresponding maximum allowable antenna ratio set in step S120 (S160: YES), the determination section 300 outputs OK information to the display section 320 so as to display the OK information (S200). The designer, after recognizing the OK information, ends designing of the semiconductor device. The design data generated in the above process includes data on the structures of gate insulating film, gate electrodes, and upper layer wirings.

In a semiconductor device manufacturing line, the semiconductor device having gate insulating films, gate electrodes, and upper layer wirings formed according to the design data stored in the design DB 220 is manufactured.

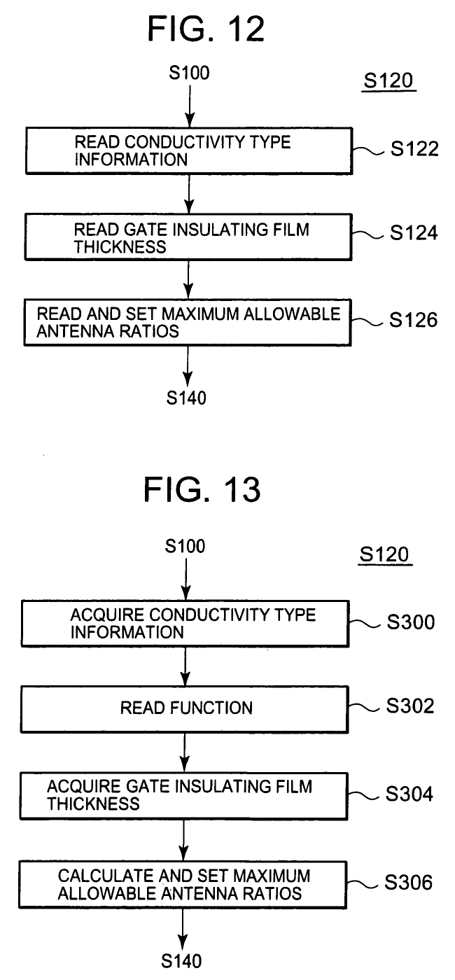

FIG. 12 is a flowchart showing first example details of the maximum allowable antenna ratio setting process (S120) shown in FIG. 11. In this example process, the maximum allowable antenna ratio setting section 280 uses the maximum allowable antenna ratio table 270. First, the gate film information acquisition section 260 of the design support system reads the conductivity type information indicating the conductivity type of each transistor from the design DB 220 (S122). The gate film information acquisition section 260 then reads the gate insulating film thickness of each transistor also from the design DB 220 (S124). Next, for each transistor, the maximum allowable antenna ratio setting section 280 reads, from the maximum allowable antenna ratio table 270, the wiring antenna ratio, via-hole antenna ratio, contact antenna ratio, and pad antenna ratio corresponding to the conductivity type and film thickness combination read from the design DB 220, and sets the antenna ratios thus read out as the maximum allowable wiring antenna ratio, via-hole antenna ratio, contact antenna ratio, and pad antenna ratio for each transistor (S126). The process of step S126 is performed for every transistor.

FIG. 13 is a flowchart showing second example details of the maximum allowable antenna ratio setting process (S120) shown in FIG. 11. In this example process, the maximum allowable antenna ratio setting section 280 uses the information held in the maximum allowable antenna ratio function holding section 340. First, the gate film information acquisition section 260 of the design support system reads the conductivity type information indicating the conductivity type of each transistor from the design DB 220 (S300). The maximum allowable antenna ratio setting section 280 reads function data corresponding to the conductivity type read out in step S300 from the maximum allowable antenna ratio function holding section 340 (S302).

The gate film information acquisition section 260 reads the gate insulating film thickness of each transistor from the design DB 220 (S304) The maximum allowable antenna ratio setting section 280 then calculates, for each transistor, a maximum allowable wiring antenna ratio, via-hole antenna ratio, contact antenna ratio, and pad antenna ratio by assigning the film thickness read out in step S304 to the function read out in step S302, and sets the calculated values as the maximum allowable antenna ratios (S306).

As described above, in cases where the maximum allowable wiring antenna ratio, via-hole antenna ratio, contact antenna ratio, and pad antenna ratio are set according to the gate insulating film thickness, the designer can set concrete maximum allowable antenna ratio values using the design support system.

When the gate insulating film is thicker or thinner than a certain value, the design support system sets a less strict maximum allowable wiring antenna ratio, via-hole antenna ratio, contact antenna ratio, and pad antenna ratio. This increases flexibility in designing a semiconductor device.

When the maximum allowable antenna ratio setting section 280 uses the maximum allowable antenna ratio table 270, processing to be performed to set maximum allowable antenna ratios is reduced. When the maximum allowable antenna ratio setting section 280 uses the information held in the maximum allowable antenna ratio function holding section 340, the maximum allowable antenna ratio setting section 280 can set finely classified maximum allowable antenna ratios.

The design support system determines whether the wiring antenna ratios, via-hole antenna ratios, contact antenna ratios, and pad antenna ratios of the designed semiconductor device are either equal to or lower than the corresponding maximum allowable antenna ratios and displays the results of determination. Therefore, when any antenna ratio of the designed semiconductor device exceeds the corresponding maximum allowable antenna ratio, the designer can recognize it without fail. This makes it possible, when the designed semiconductor device is manufactured in a manufacturing line, to prevent the gate insulating film used in the semiconductor device from deteriorating.

### Second Embodiment

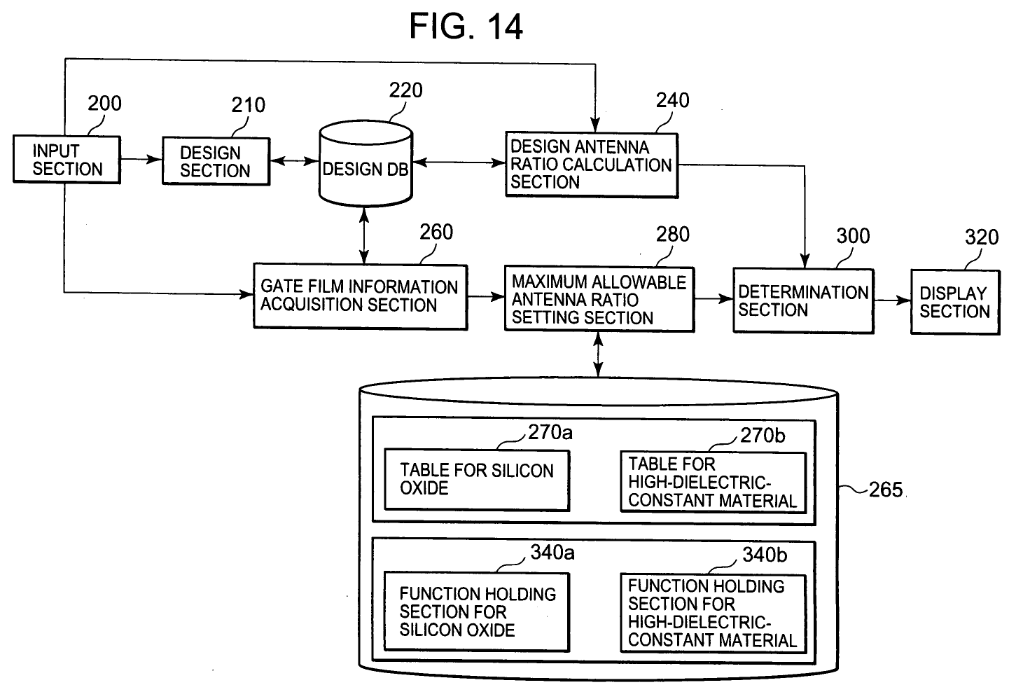

FIG. 14 is a block diagram of the configuration of a design support system according to a second embodiment of the present invention. The design support system shown in FIG. 14 is configured the same as the design support system shown in FIG. 1 except that the maximum allowable antenna ratio setting information holding section 265 includes, instead of the maximum allowable antenna ratio table 270, a maximum allowable antenna ratio table for silicon oxide (hereinafter referred to as the “table for silicon oxide”) 270a and a maximum allowable antenna ratio table for high-dielectric-constant material (hereinafter referred to as the “table for high-dielectric-constant material) 270b and, instead of the maximum allowable antenna ratio function holding section 340, a maximum allowable antenna ratio function holding section for silicon oxide (hereinafter referred to as the “function holding section for silicon oxide”) 340a and a maximum allowable antenna ratio function holding section for high-dielectric-constant material (hereinafter referred to as the “function holding section for high-dielectric-constant material”) 340b. The method of designing a semiconductor device using the design support system shown in FIG. 14 is the same as described for the first embodiment with reference to FIG. 11 except for details of the maximum allowable antenna ratio setting process (S120 of FIG. 11). In the following, therefore, description of sections other than the table for silicon oxide 270a, table for high-dielectric-constant material 270b, function holding section for silicon oxide 340a, and function holding section for high-dielectric-constant material 340b of the design support system shown in FIG. 14 will be omitted. As for the method of designing a semiconductor device, description of processes other than the maximum allowable antenna ratio setting process will be omitted.

The table for silicon oxide 270a is used when the gate insulating film is formed of silicon oxide. The table for high-dielectric-constant material 270b is used when the gate insulating film is formed of a high-dielectric-constant material. The table for silicon oxide 270a and table for high-dielectric-constant material 270b have a data configuration approximately the same as that of the maximum allowable antenna ratio table 270 used in the first embodiment.

The function holding section for silicon oxide 340a holds data representing a function for use when the gate insulating film is formed of silicon oxide. The function holding section for high-dielectric-constant material 340b holds data representing a function for use when the gate insulating film is formed of a high-dielectric-constant material. The function represented by the data held in the function holding section for silicon oxide 340a and the function represented by the data held in the function holding section for high-dielectric-constant material 340b are approximately identically shaped as the function used in the first embodiment.

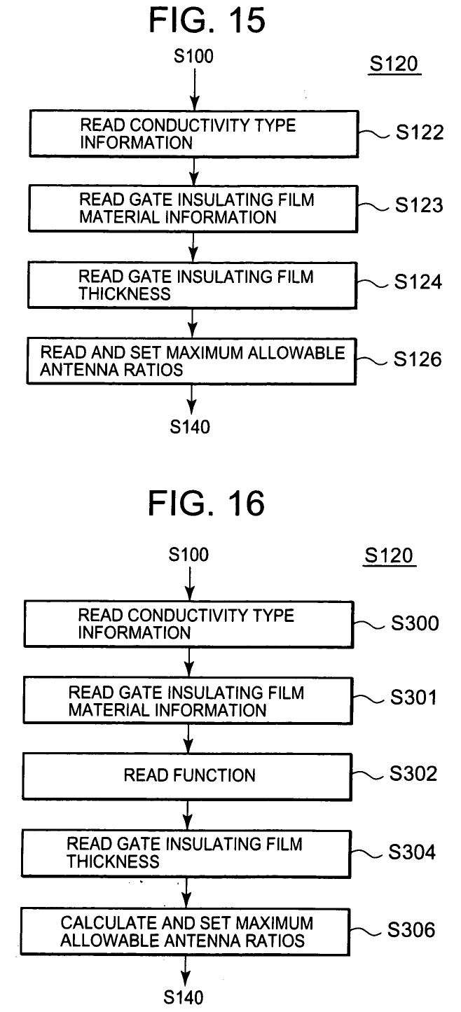

FIG. 15 is a flowchart for explaining a first example process for setting maximum allowable antenna ratios using the design support system shown in FIG. 14. In this example process, the maximum allowable antenna ratio setting section 280 uses the table for silicon oxide 270a and table for high-dielectric-constant material 270b. First, the gate film information acquisition section 260 of the design support system reads the conductivity type information indicating the conductivity type of each transistor from the design DB 220 (S122). The gate film information acquisition section 260 then reads the material information indicating the gate insulating film material of each transistor from the design DB 220 (S123).

The gate film information acquisition section 260 reads the gate insulating film thickness of each transistor from the design DB 220 (S124). Next, for each transistor, the maximum allowable antenna ratio setting section 280 reads, from whichever of the table for silicon oxide 270a and table for high-dielectric-constant material 270b corresponds to the material information read in step S123, the wiring antenna ratio, via-hole antenna ratio, contact antenna ratio, and pad antenna ratio corresponding to the combination of the conductivity type read in step S122 and film thickness read in step S124. The maximum allowable antenna ratio setting section 280 sets the antenna ratios thus read out as the maximum allowable wiring antenna ratio, via-hole antenna ratio, contact antenna ratio, and pad antenna ratio for each transistor (S126). The process of step S126 is performed for every transistor.

FIG. 16 is a flowchart for explaining a second example process for setting maximum allowable antenna ratios using the design support system shown in FIG. 14. In this example process, the maximum allowable antenna ratio setting section 280 uses the information held in the function holding section for silicon oxide 340a and function holding section for high-dielectric-constant material 340b. First, the gate film information acquisition section 260 of the design support system reads the conductivity type information indicating the conductivity type of each transistor from the design DB 220 (S300). The gate film information acquisition section 260 then reads, for each transistor, the gate insulating film material information from the design DB 220 (S301). The maximum allowable antenna ratio setting section 280 reads function data corresponding to the combination of the conductivity type information read in step S300 and the material information read in step S301 from the maximum allowable antenna ratio setting information holding section 265 (S302). The subsequent processing is the same as done, as shown in FIG. 13, in the first embodiment, so that its explanation is omitted.

As described above, the second embodiment of the present invention can produce advantageous effects similar to those produced by the first embodiment. In the second embodiment, the maximum allowable antenna ratios can be made different according to the gate insulating film material. This makes it possible to set less strict maximum allowable antenna ratios. In the second embodiment, when the gate insulating film is formed of high-dielectric-constant material, the gate insulating film thickness may be represented either by a physical thickness or by an equivalent oxide thickness. An equivalent oxide thickness is determined by: (silicon oxide dielectric constant/dielectric constant of high-dielectric-constant material)×physical film thickness.

### Third Embodiment

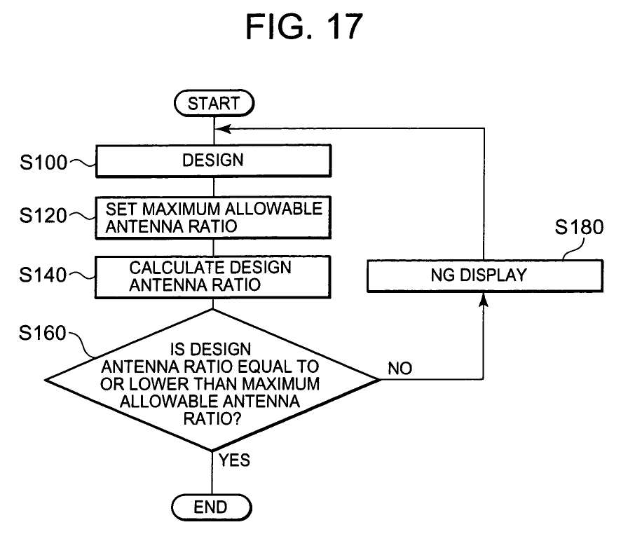

FIG. 17 is a flowchart for explaining operation of a design support system according to a third embodiment of the present invention. The configuration of the design support system according to the third embodiment is similar to those of the design support systems according to the first and second embodiments, so that its explanation is omitted. In the third embodiment, the design support system automatically designs wiring.

To be concrete, the design section 210 designs various wirings, pads, contacts, and via-holes which are connected to a gate electrode. The design data is stored in the design DB 220 (S100). When designing in step S100 is finished, the design support system sets, for each transistor, a maximum allowable wiring antenna ratio, via-hole antenna ratio, contact antenna ratio, and pad antenna ratio (S120). The details of this process are similar to those of the corresponding processes performed in the first and second embodiments.

The design antenna ratio calculation section 240 of the design support system calculates, for each transistor included in the designed semiconductor device, the wiring antenna ratio, via-hole antenna ratio, contact antenna ratio, and pad antenna ratio (S140). The details of this process are similar to those of the corresponding processes performed in the first and second embodiments.

The determination section 300 of the design support system determines whether the wiring antenna ratio, via-hole antenna ratio, contact antenna ratio, and pad antenna ratio calculated for each transistor in step S140 are either equal to or lower than the corresponding maximum allowable antenna ratios set in step S120 (S160). If any antenna ratio calculated, in step S140, for any transistor is found to be higher than the corresponding maximum allowable antenna ratio set in step S120 (S160: NO), the determination section 300 outputs NG information specifying the particular transistor to the display section 320. The display section 320 displays the inputted NG information (S180). Subsequently, the wirings, pads, contacts, and via-holes are re-designed for the particular transistor (S100). In the procedure, the NG information need not necessarily be displayed.

When no antenna ratio calculated in step S140 is found to be higher than the corresponding maximum allowable antenna ratio set in step S120 (S160: YES), the design support system ends designing of the wirings, pads, contacts, and via-holes. According to the present embodiment, even in cases where the design support system automatically designs various wirings, contacts, and via-holes, it is possible to set concrete values of maximum allowable wiring antenna ratios, via-hole antenna ratios, contact antenna ratios, and pad antenna ratios according to the gate insulating film thickness.

The design support systems according to the first, second, and third embodiments are realized by installing a program for realizing the functions of the design section 210, design DB 220, design antenna ratio calculation section 240, gate film information acquisition section 260, maximum allowable antenna ratio table 270, maximum allowable antenna ratio setting section 280, and determination section 300 in a computer. Such a program may be installed in a computer via a recording medium or it may be downloaded from a server via a communication line, for example, using the Internet. The recording medium may be, for example, a flexible disk, hard disk, or semiconductor memory.

Embodiments of the present invention have been described above with reference to drawings for illustrative purposes, but the invention can also be applied in various different configurations than those described above. For example, the maximum allowable antenna ratio setting section 280 may use the maximum allowable antenna ratio table 270 (or the table for silicon oxide 270a and table for high-dielectric-constant material 270b) for some of the transistors included in a semiconductor device whereas using information held in the maximum allowable antenna ratio function holding section 340 (or the function holding section for silicon oxide 340a and function holding section for high-dielectric-constant material 340b) for the other transistors included in the same semiconductor device.

In the above embodiments, the maximum allowable antenna ratio setting section 280 sets different maximum allowable antenna ratios for different gate insulating film thicknesses. Since gate insulating film thicknesses are dependent on transistor drive voltages, the maximum allowable antenna ratio setting section 280 may set maximum allowable antenna ratios according to transistor drive voltages. In such a case, too, the configurations of the design support systems according to the above embodiments can be used by having the gate insulating film thicknesses replaced with relevant transistor drive voltages.

What is claimed is:

1. A design support system comprising:
a gate film information acquisition section which acquires a film thickness of a gate insulating film; and
a maximum allowable antenna ratio setting section which sets a maximum allowable antenna ratio for a gate electrode positioned on the gate insulating film and which makes the maximum allowable antenna ratio different according to the film thickness acquire by the gate film information acquisition section.

2. The design support system according to claim 1, wherein:
when the film thickness is in a first range, the maximum allowable antenna ratio setting section sets the maximum allowable antenna ratio to a value lower than a value to which the maximum allowable antenna ratio is set when the film thickness is in one of a second range and a third range, the film thickness in the second range being thinner than the film thickness in the first range, the film thickness in the third range being thicker than the film thickness in the first range.

3. The design support system according to claim 2, wherein:
the first range includes a film thickness at which a tunneling current starts flowing in the gate insulating film.

4. The design support system according to claim 3, wherein:
the film thickness at which a tunneling current starts flowing in the gate insulating film is 2.6 nm.

5. The design support system according to claim 1, further comprising:
a design antenna ratio calculation section which calculates a design antenna ratio based on design data on wiring to be connected to the gate electrode; and
a determination section which determines whether the design antenna ratio is either equal to or lower than the maximum allowable antenna ratio.

6. The design support system according to claim 1, wherein:
the maximum allowable antenna ratio setting section sets the maximum allowable antenna ratio based on a table in which the film thickness and the maximum allowable antenna ratio is associated with each other.

7. The design support system according to claim 1, wherein:
the maximum allowable antenna ratio setting section sets the maximum allowable antenna ratio based on a function which includes an independent variable representing the film thickness and a dependent variable representing the maximum allowable antenna ratio.

8. The design support system according to claim 7, wherein:
the function is approximately U-shaped or V-shaped with an extremal value represented by a bottom portion thereof or approximately U-shaped having a horizontal bottom portion.

9. The design support system according to claim 1, wherein:
the film thickness is a physical thickness of the gate insulating film.

10. The design support system according to claim 1, wherein:
the film thickness is an equivalent oxide thickness.

11. The design support system according to claim 1, wherein:
the gate film information acquisition section acquires conductivity type information indicating whether a transistor formed by the gate insulating film is of a P-channel type or of an N-channel type; and
the maximum allowable antenna ratio setting section makes the maximum allowable antenna ratio different according to the conductivity type information.

12. The design support system according to claim 1, wherein:
the gate film information acquisition section acquires material information indicating a material of the gate insulating film; and
the maximum allowable antenna ratio setting section makes the maximum allowable antenna ratio different according to the material information.

13. A computer readable medium storing a program executed in a computer, the program comprising:
acquiring a film thickness of a gate insulating film; and
setting a maximum allowable antenna ratio for a gate electrode positioned on the gate insulating film and varying the maximum allowable antenna ratio according to the film thickness read by the first function of the gate insulating film.

14. A method of designing a semiconductor device, comprising:
generating design data on wiring to be connected to a gate electrode;
having a computer set a maximum allowable antenna ratio for the gate electrode;
having the computer calculate an antenna ratio of the gate electrode using the design data; and
having the computer determine whether the calculated antenna ratio is either equal to or smaller than the maximum allowable antenna ratio and output a result of determination;
wherein, in the step of setting the maximum allowable antenna ratio, the computer makes the maximum allowable antenna ratio different according to the film thickness of a gate insulating film under the gate electrode.

15. A method of manufacturing a semiconductor device, comprising:
designing, by the design method according to claim 14, a semiconductor device including a gate insulating film, a gate electrode, and an upper layer wiring; and
manufacturing the semiconductor device according to a design which is designed in the step of designing.
